(19) United States
(12) Patent Application Publication
(10) Pub. No.: US 2026/0068529 A1
(43) Pub. Date: Mar. 5, 2026

(54) OFF-AXIS CORRECTION USING ANGULAR ADJUSTMENT MECHANISM

(71) Applicant: Applied Materials, Inc., Santa Clara, CA (US)

(72) Inventors: Ayra SEARS, Santa Clara, CA (US); Andrew KOLL, Santa Clara, CA (US); Zachary DUNN, Santa Clara, CA (US); Timothy THOMAS, Portland, OR (US)

(21) Appl. No.: 18/821,290

(22) Filed: Aug. 30, 2024

(51) Int. Cl. H10N 30/80; H10N 30/20

(52) U.S. Cl. CPC H10N 30/802; H10N 30/206

(57) ABSTRACT

Aspects generally relate to methods and systems for correcting off-axis motion by using an angular adjustment mechanism. The linear actuator includes a body, a non-moving section extending from the body, and an angular adjustment mechanism secured on the non-moving section, wherein the angular adjustment mechanism corrects off-axis motion relative to an ideal axis of travel of the linear actuator. The angular adjustment mechanism includes a first compensation wedge and a second compensation wedge. The first compensation wedge and the second compensation wedge are arranged to form a rectangular shape. A run-out measurement device measures run-out at different angles to identify a run-out vector.

### BACKGROUND

### Field

Aspects generally relate to methods and systems for off-axis correction of linear actuators.

### Description of the Related Art

Off-axis errors are significant considerations in the operation of linear actuators, particularly in applications demanding high precision and accuracy. These errors refer to deviations from the intended linear path of motion, where the actuator's movement strays from the ideal axis relative to a reference plane. Such deviations can arise due to mechanical imperfections, assembly misalignments during installation, or environmental factors like thermal expansion. Off-axis errors can adversely affect the performance of systems such as semiconductor manufacturing equipment. Mitigating these errors often involves meticulous alignment procedures, advanced calibration techniques, and the use of precision instrumentation to ensure that the actuators operate within specified tolerances. Addressing off-axis errors contributes to achieving consistent, reliable performance in various industrial and technological applications.

Therefore, there is a need for an improved off-axis correction mechanism for linear actuators.

### SUMMARY

Aspects generally relate to methods and systems for correcting off-axis motion by using an angular adjustment mechanism.

In one implementation, a linear actuator includes a body, a non-moving section extending from the body, and an angular adjustment mechanism secured on the non-moving section, wherein the angular adjustment mechanism corrects off-axis motion relative to an ideal axis of travel of the linear actuator.

In one implementation, a linear actuator includes a body, a moving section extending from the body, and an angular adjustment mechanism secured between a non-moving section and a non-moving lens stack, wherein the angular adjustment mechanism corrects off-axis motion relative to an ideal axis of travel of the linear actuator.

In one implementation, a method includes securing an angular adjustment mechanism to a linear actuator, mounting the linear actuator to a run-out measurement device, measuring, by the run-out measurement device, run-out at different angles to identify a run-out vector, and adjusting an angular alignment to minimize off-axis motion from an ideal axis of travel determined by the run-out measurement device.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 illustrates a linear actuator including compensation wedges for correcting off-axis motion, the compensation wedges installed on a non-moving leg of the linear actuator, according to one implementation.

FIG. 2 illustrates a linear actuator including compensation wedges for correcting off-axis motion, the compensation wedges integrated to a non-moving lens stack and a moving lens stack, according to one implementation.

FIG. 3 is a flowchart of a method for implementing the linear actuator including compensation wedges for correcting off-axis motion of FIG. 1, according to one implementation.

FIG. 4 is a flowchart of a method for implementing the linear actuator including compensation wedges for correcting off-axis motion of FIG. 2, according to one implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Aspects generally relate to methods and systems for correcting off-axis motion by using an angular adjustment mechanism.

A linear actuator is a device that creates motion in a straight line, as opposed to the rotational motion of a typical electric motor. A linear actuator may, e.g., convert rotational motion into push or pull linear motion. The main types of linear actuators include electromechanical actuators, hydraulic actuators, pneumatic actuators, and piezoelectric actuators. Piezoelectric actuators use piezoelectric materials that expand or contract when an electric voltage is applied, providing extremely precise linear movement.

In one example, linear actuators can experience misalignment from a reference plane on their surface, which can affect their performance and longevity. In another example, linear actuators can be manufactured such that their axis of travel is misaligned from a theoretical (or ideal) axis of travel. Common causes of misalignment in linear actuators include at least load mismanagement, wear and tear, thermal expansion, and mechanical deformation. Over time, components within the linear actuator can wear unevenly, leading to misalignment. In the example embodiments, the misalignment being corrected for is a tiny manufacturing difference between each linear actuator.

The example embodiments provide for an angular adjustment mechanism installed or incorporated or secured onto a linear actuator. The angular adjustment mechanism can correct the off-axis motion from a theoretical ideal axis of travel. The angular adjustment mechanism includes compensation wedges. In one example, the angular adjustment mechanism includes, e.g., a single wedge or a combination of a first wedge and a second wedge or simply wedges. The compensation wedges may be installed on a non-moving leg of the linear actuator. In another example, the compensation wedges may be incorporated or integrated to a non-moving lens stack associated with the linear actuator. The angular adjustment mechanism top surface becomes the new mounting surface of the linear actuator, representing its reference plane. This allows for the alignment of the linear real-axis of travel of the linear actuator with respect to the new mounting surface or reference plane. Thus, the mounting face is changed from being a part of the linear actuator to being a part of the wedges. The new reference surface uses rotational degrees of freedom to align the real-axis of travel to the theoretical axis of travel, which is now perpendicular to the new reference surface. Stated differently, the travel of the moving leg is perpendicular to the mounting surface.

The system provides for process optimization to increase the yield by incorporating or installing an angular adjustment mechanism with a linear actuator to correct for off-axis motion from the theoretical or ideal axis of travel. The angular adjustment mechanism is positioned between the reference surface and the linear actuator. The limitations (e.g., real off-axis true motion) become the residuals of this optimized axis travel (non-linearity/noise). By measuring the off-axis motion once, the system can determine the travel vector of the linear actuator and align its travel vector to become perpendicular to the reference surface. Once compensated, the system can re-measure the off-axis motion to determine the new aligned off-axis motion. In short, the system aligns the real or actual or realized axis of travel to the ideal axis of travel, rather than keeping the real axis of travel to the theoretical axis of travel as an error in linear actuator production. The real versus ideal errors that are being corrected for are very small as they are intrinsic to each individual linear actuator. Stated differently, the issue is that the axis of travel may not be perpendicular to a mounting datum. As such, the current approach redefines the mounting datum to be perpendicular to the axis of travel.

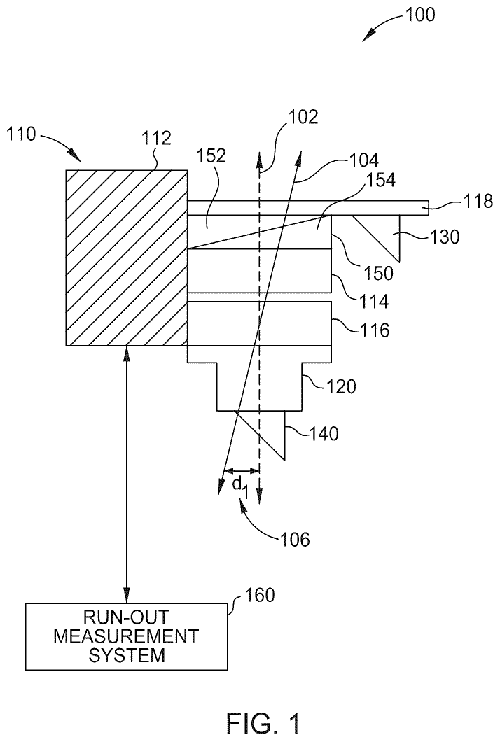

FIG. 1 illustrates a linear actuator including compensation wedges for correcting off-axis motion, the compensation wedges installed on a non-moving leg of the linear actuator, according to one implementation.

The system 100 includes a linear actuator 110 mounted or secured to a part of a run-out measurement system 160 (or run-out measurement device). In one example, the linear actuator 110 may be a piezo actuator. A piezo actuator uses piezoelectric materials that expand or contract when an electric voltage is applied, providing precise linear movement.

The linear actuator 110 includes a body 112, a non-moving leg 114, a moving leg 116, and a bottom surface 118 of a component of the run-out measurement system 160. The non-moving leg 114 and the moving leg 116 may be referred to as a pair of legs.

Therefore, the linear actuator 110 includes moving legs and non-moving legs. The moving leg actively moves when the linear actuator 110 is in operation. The moving leg typically supports the element that translates motion. The non-moving leg 114 of the linear actuator 110 remains stationary during operation. The non-moving leg 114 typically provides stability and support for the linear actuator 110 and anchors the linear actuator 110 to the base or frame of the device.

The coordination between the moving legs and the non-moving legs ensures that the linear actuator 110 can deliver precise linear motion without misalignment or unwanted shifts. The non-moving leg provides a stable foundation, while the moving leg handles the dynamic aspect of motion, working together to achieve precise positioning.

The payload mechanism represents (by mass and center of gravity) the final moving lens assembly while mounting, e.g., the measurement prism to the moving leg 116. The measurement prism is used by the run-out measurement system 160 to track the run-out. The payload 120 accurately tracks the run-out as the piezo moves because it weighs the same as the final lens assembly and has an aligned center of gravity with that of the final moving lens assembly. Stated differently, the payload 120 simulates the object, device, or load that the linear actuator 110 is designed to move or control. The term payload mechanism may refer to the structure or system through which the linear actuator 110 interfaces with and moves the payload 120. The linear actuator 110 provides the force and motion to move the payload mechanism. The payload mechanism matches the mass of the final assembly to be mounted onto the moving leg 116 and has a center of gravity positionally aligned to the center of gravity axis of travel of the final assembly mounted onto the moving leg 116.

A first prism 130 may be attached to the bottom surface 118 of a component of the run-out measurement system 160. The first prism 130 is denoted as a reference prism. The reference prism references the mounting surface of the linear actuator 110 or the wedges which hold the linear actuator 110. The reference prism is used to subtract the noise in the air/room from the measurement prism's run-out values. It is noted that the plane of the front face of both prisms is aligned, not just in angle but in space. The ideal axis of travel runs through both prism's planes, and ideally, runs down the center of the measurement prism's face plane.

A second prism 140 may be attached to the payload 120. The second prism 140 is denoted as a measurement prism. The measurement prism is an optical component used to determine the position, orientation or alignment of the payload 120 to which it is attached. The measurement prism reflects or refracts light in a way that can be measured to determine the exact position or alignment of the payload 120. When the measurement prism is attached to the payload 120, the measurement prism allows for real-time monitoring of the payload's position and orientation. The measurement prism provides precise feedback on the payload's position relative to the reference prism or other fixed points in the system 100.

The combination of the first prism 130 and the second prism 140 allows for very accurate measurements of displacement, rotation, and alignment. As such, the reference prism and the measurement prism work together to provide precise positioning, alignment, and measurement capabilities in the system 100.

In other examples, the first prism 130 and the second prism 140 may be replaced with a single measurement device. The measurement device may or may not include prisms. For example, the measurement device may include linear encoders, laser displacement sensors, accelerometers, etc. The use of a first prism 130 in cooperation with a second prism 140 is presented for illustration purposes only. Any type of measurement device may be used to measure run-out.

An angular adjustment mechanism 150 is positioned or attached or integrated or secured between the bottom surface 118 (also referred to as a reference surface) and the non-moving leg 114 of the linear actuator 110. The angular adjustment mechanism 150 is positioned between the body 112 of the linear actuator 110 and the first prism 130 (i.e., the reference prism). The angular adjustment mechanism 150 directly contacts the bottom surface 118 and a surface (e.g., a top surface) of the non-moving leg 114. The angular adjustment mechanism 150 does not contact the first prism 130. The angular adjustment mechanism 150 may be vertically aligned with the non-moving leg 114 and the moving leg 116.

In one example, the width of the angular adjustment mechanism 150 is equal to the width of the non-moving leg 114 and the moving leg 116. The angular adjustment mechanism 150 may be vertically aligned with the second prism 140 (i.e., the measurement prism).

The angular adjustment mechanism 150 may include, e.g., a first compensation wedge 152 and a second compensation wedge 154. A compensation wedge is a precision tool used to correct alignment errors in the mounting of linear actuators or piezo actuators. In another embodiment, the compensation wedge is a single wedge cut to correct the measured angle error between the real-axis of travel and the ideal axis of travel. It is particularly useful for addressing static wedge errors, where the actuator's axis of motion is not perfectly perpendicular to the reference plane or reference surface. By installing a compensation wedge on the non-moving leg of the linear actuator, precise alignment can be achieved and off-axis motion can be minimized. The reference plane is a stable, flat surface that serves as the baseline for alignment. In particular, a reference datum serves as the baseline or standard against which the movement and position of the linear actuator 110 are measured. Stated differently, the reference plane represents the mounting surface of the linear actuator 110. The travel of the moving leg is perpendicular to the mounting surface. When the linear actuator 110 is mounted, it is desired to know that its travel is aligned perpendicular to the mounting plane. A reference datum can be a surface or plane on an object used as a basis for measurement. For the linear actuator 110, the reference datum provides a consistent and precise starting point for its movement. The reference datum ensures the travel and position of the linear actuator 110 can be accurately controlled and measured relative to a known position.

Further, a compensation wedge is a thin, typically adjustable, shim or plate that can be inserted between the actuator's mounting base and the reference surface. A compensation wedge has a tapered design, which allows for fine-tuning the angle at which the actuator is mounted. The main purpose of a compensation wedge is to correct angular misalignment, ensuring that the actuator's axis of travel is perfectly perpendicular to the reference plane. This alignment is valuable for maintaining precision and accuracy in applications such as semiconductor processing. After initial measurement before the angular misalignment is compensated, the linear actuator 110 is measured. Once its error is measured and calculated, it can then be compensated for using the angular adjustment mechanism. Then, it can be re-measured again to iterate the process.

Moreover, in one example, the run-out can be re-measured to determine how close the run-out is to zero. Thus, a continuous feedback loop of measurement, adjustment (i.e., re-alignment), and redefinition can be provided to ensure precise and accurate perpendicular travel to the reference plane or reference surface.

The first compensation wedge 152 is secured to the second compensation wedge 154 such that together they are arranged to form, e.g., a rectangle or rectangular shape in a 2D cross-sectional view. The first compensation wedge 152 directly contacts the surface of the bottom surface 118, whereas the second compensation wedge 154 directly contacts the non-moving leg 114. The angular adjustment mechanism 150 is secured between the body 112 of the linear actuator, the non-moving leg 114, and the bottom surface 118.

The purpose of using two opposing compensation wedges is to address a continuous range of azimuthal and elevation angles. In other words, the compensation wedges may be twisted relative to each other to point the correction vector at any angle around the axis of travel, and with a range of magnitudes of an elevation angle to be corrected (that is the difference between the axis of travel and the axis perpendicular to the original mounting datum). This is valuable because it underlines the flexibility of this approach to correct any actuator in a population of sibling actuators that each have a slightly different walk out, without needing a custom solution for every device.

The wedge approach can only correct linear deviations in the runout of an actuator. If the runout is characteristically non-linear, the residual may be large. A weak, yet present quadratic term is observed in the runout. Thus, the wedge approach offers a fixed angular change in the mounting datum, which corresponds to a linear shift in position with travel. Any other random runout with the piezo travel will be reduced only by the linear component of the total magnitude. As such, the linear term should be the largest part of the runout, which is acceptable and preferred.

Incorporating an angular alignment or adjustment mechanism between a linear actuator and its reference surface can help maintain proper alignment and enhance the performance and longevity of the linear actuator. In semiconductor manufacturing, precision and alignment are beneficial to ensure high yields and reduce defects. Integrating an angular alignment or adjustment mechanism with a linear actuator can enhance the accuracy and reliability of equipment used in this process. Moreover, the angular alignment or adjustment mechanism is integrated directly into the linear actuator 110, before the linear actuator 110 is integrated into other systems. As such, the angular alignment or adjustment mechanism is intrinsic to the device (i.e., the linear actuator 110) and if adjusted does not propagate by angular or positional changes through components attached to the moving leg 116. Once aligned, any piezo and angular alignment pair can be placed into any device and need no adjustment. In other words, run-out is dealt with at the source so as to not affect downstream processes or components. In applications demanding extremely high precision, such as semiconductor manufacturing, even the smallest deviation can be critical. Thus, the reason why it is important to fix the piezo's angular alignment by itself is to remove otherwise iterative optical alignment steps, which take significant time and are difficult to perfectly align due to coupled motion effects. Changing one angular alignment can change a positional alignment, which causes the alignment of both simultaneously to be difficult if performed on the lens.

The linear actuator 110 is mounted or secured onto a run-out measurement system 160 (or run-out measurement device). A run-out measurement mechanism is a device or system used to measure the deviation from a point. Run-out is commonly measured on rods/axles. In the example embodiments, the run-out 106 is the change along a measurement axis (an axis pointing at the face of the prisms) backwards and forwards along it. In short, the run-out 106 is perpendicular to the face of the prisms.

The process of using the run-out measurement system 160 may include mounting the piezo, adjusting the angular alignment of the measurement prism until it is aligned with the reference prism, and then performing a measurement. The rotation, mounting, alignment, and measurement occurs for different angles (e.g., 0 degrees, 45 degrees, 90 degrees). Finally, all the data is analyzed.

The run-out deviation (or the run-out 106) is measured as a positional difference over a length of travel, providing the real axis of travel (after accounting for the 3D nature of measuring the different angles). The system then compensates by aligning the real axis of travel to the ideal axis of travel. Stated differently, the issue is that the axis of travel may not be perpendicular to a mounting datum. As such, the current approach redefines the mounting datum to be perpendicular to the axis of travel.

The benefits of employing run-out compensation include improved accuracy to ensure the linear actuator 110 moves along the desired path with minimal deviation, increased yield to enhance the precision of semiconductor processing, leading to higher yield rates and reduced defects to minimize errors that could result in defective products. Tight overlay tolerances enable the production of smaller and taller electrical lines.

The run-out measurement system 160 measures the run-out 106 at different angles. For example, the run-out measurement system 160 measures the run-out 106 at 0 degrees, at 45 degrees, and at 90 degrees to identify a vector or vectors of the run-out. The run-out 106 is generally an approximate linear relationship in the plane of the different angle measurements at a specific angle. By measuring three times at three different angles, different portions of the run-out vector are determined, which enables the approximation of the true magnitude and angle of the run-out 106. The run-out is compensated or adjusted using the angular adjustment mechanism 150 to align the reference mounting surface perpendicular to the axis of travel 102. Optimizing the linear off-axis motion of the linear actuator 110 with respect to a reference surface is valuable in applications that demand high precision and accuracy, such as semiconductor manufacturing. The primary reasons for optimization include increased precision and accuracy, enhanced yield and quality, reduced wear and tear, energy efficiency, cost savings, improved performance for downstream processes, adherence to industry standards, and ensuring regulatory compliance.

In operation, the angular adjustment mechanism 150 is installed or integrated or secured to the linear actuator 110. The angular adjustment mechanism 150 includes a pair of compensation wedges. The linear actuator 110 is then mounted or secured onto the run-out measurement system 160. The payload 120 is mounted to the moving legs of the linear actuator 110. The run-out 106 is measured at different angular positions (e.g., 0 degrees, 45 degrees, 90 degrees, etc.) to identify a vector of the run-out. The angular adjustment mechanism 150 with the pair of compensation wedges is used to compensate or adjust for the real axis of travel perpendicularly to the reference mounting face. The run-out measurement is repeated for different angles until the ideal axis of travel 102 is aligned with the real axis of travel 104, minimizing the run-out 106. Once alignment has been achieved, the pair of compensation wedges of the angular adjustment mechanism 150 are locked. In other words, once the linear actuator 110 is precisely aligned, the adjustment mechanism (i.e., angular adjustment mechanism 150) is locked in place using, e.g., adhesives, bolts, screws, or clamps to ensure all components are securely fastened to prevent any movement during operation. As noted above, a single wedge cut to the correct angle can be used to replace the two adjustable wedges.

As a result, the angular adjustment mechanism 150 increases precision and accuracy in minimizing residuals and improves process control. Off-axis motion introduces deviations from the intended path, which can lead to inaccuracies. Optimizing the alignment ensures that the actuator moves precisely along the desired axis, reducing residuals. High precision in linear motion is beneficial for controlling processes that involve exact positioning, such as photolithography and etching in semiconductor manufacturing. Enhanced yield and quality result in consistent outcomes and reduced defects. Higher precision and fewer defects result in lower scrap rates and rework, reducing overall production costs. Improved performance of downstream processes results in precision alignment and better integration. Accurate positioning of components ensures that subsequent processes (e.g., bonding, packaging) are performed accurately, enhancing the overall performance of the manufacturing line. Optimized linear motion using the angular adjustment mechanism 150 facilitates better integration with other automated systems and robotic components, improving overall workflow efficiency. Semiconductor manufacturing procedures often demand adherence to strict industry standards for precision and quality. Optimizing off-axis motion using the angular adjustment mechanism 150 helps meet these standards.

By addressing off-axis motion and ensuring precise alignment with a reference surface, semiconductor manufacturers can achieve higher yields, better quality products, and more efficient and cost-effective production processes.

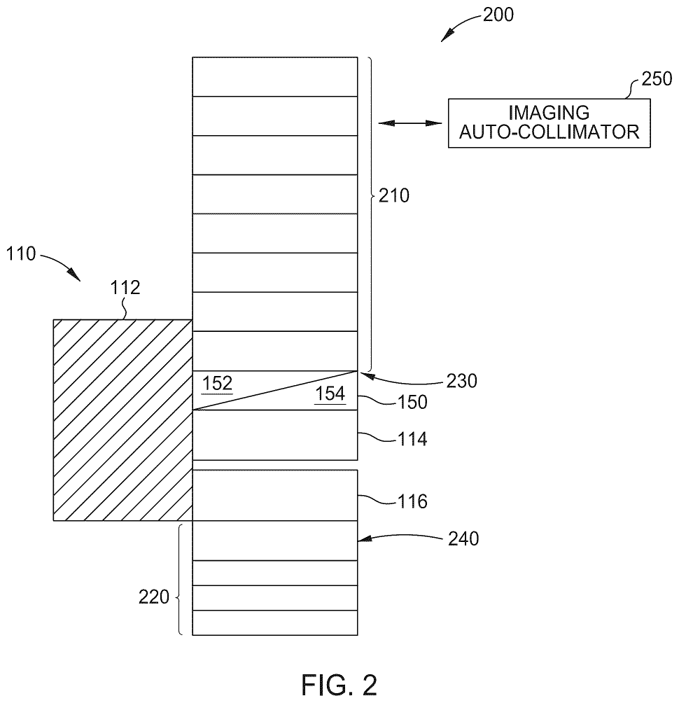

FIG. 2 illustrates a linear actuator including compensation wedges for correcting off-axis motion, the compensation wedges integrated to a non-moving lens stack and a moving lens stack, according to one implementation.

The system 200 includes a linear actuator 110 and an imaging auto-collimator 250. The linear actuator 110 includes a body 112, a non-moving leg 114, and a moving leg 116.

The linear actuator 110 may support a non-moving lens stack 210 and a moving lens stack 220. The non-moving lens stack 210 remains fixed in position and serves as a stable mounting base for the linear actuator 110, angular adjustment mechanism 150, and the moving lens stack 220. The moving lens stack 220 is coupled to the linear actuator 110, which can precisely move the attached lens stack up and down. The linear actuator 110 has a real axis of travel that determines the optical alignment error between the moving lens stack 220 and the non-moving lens stack 210.

A boresight compensator 240 is secured between the moving legs of the linear actuator 110 and the moving lens stack 220. A boresight error refers to the misalignment or deviation of an optical or electronic sighting system from its intended or nominal axis of alignment. Stated differently, now that the real-axis of travel of the piezo is aligned perpendicular to the mounting face, the non-moving lens stack 210 can have an aligned optical axis with the travel axis of the linear actuator 110. However, this will cause the moving leg to have an angle and position that is now offset by the wedge. Now, the system aligns, both in position and in angle, the moving lens stack optical axis to the non-moving lens stack optical axis. In short, the axis of travel is aligned perpendicular to the top mounting face. Due to the manufacturing method of the lens stack, the bottom surface of the non-moving stack is perpendicular to the optical axis. Now, the optical axis of the non-moving lens stack and the real travel axis are angularly aligned. By using the tolerances in the bolts it can be positionally aligned.

Using an auto-collimator, the optical axis of the non-moving lens stack can be located and the moving lens stack can be aligned to this as well with a positional alignment mechanism and angular alignment mechanism. It is likely that the positional alignment can be within the tolerance of the bolt holes, so it is likely that only another wedge will be used. Simplified further, the bottom leg is now at an angle due to the top wedges/wedge, and the system now compensates for that angle (and position change) as well.

In operation, during setup, the boresight compensator 240 aligns the moving lens stack 220 with the non-moving lens stack 210 in both position and angle.

An angular adjustment mechanism 150 is positioned or attached or integrated between the non-moving leg 114 of the linear actuator 110 and the non-moving lens stack 210. The angular adjustment mechanism 150 is positioned between the body 112 of the linear actuator 110 and the non-moving lens stack 210.

The angular adjustment mechanism 150 may include a first compensation wedge 152 and a second compensation wedge 154. A compensation wedge is a precision tool used to correct angular alignment errors in the mounting of linear actuators or piezo actuators. By securing a compensation wedge between the moving legs of the linear actuator 110 and the non-moving lens stack 210, precise alignment can be achieved and off-axis motion of the linear actuator 110 can be minimized.

In one example, the first compensation wedge 152 is secured to the second compensation wedge 154 such that together they are arranged to form a rectangle. The first compensation wedge 152 directly contacts the surface of the non-moving lens stack 210, whereas the second compensation wedge 154 directly contacts the non-moving leg 114.

The optical center and angular alignment of the non-moving lens stack 210 may be referenced using, e.g., an imaging auto-collimator 250. The imaging auto-collimator 250 is a precision optical instrument used to measure small angular deviations, align optical components, and verify the alignment of optical systems. When used to reference the optical center of a non-moving lens stack in a linear actuator system, it serves several purposes such as achieving alignment verification, providing angular measurements, providing quality control, and providing dynamic monitoring.

The imaging auto-collimator 250 measures deviations of both position and angular alignments.

In operation, the linear actuator 110 is assembled or secured to the non-moving lens stack 210. An outer wedge surface may become the reference datum. The positional alignment of the non-moving lens stack 210 is then determined using an imaging auto-collimator 250 to establish the optical center and angular alignment of the non-moving lens stack 210. The boresight compensator 240 is installed or secured to the mounting face 230 of the linear actuator 110. The moving lens stack 220 is installed or secured to the boresight compensator 240. The boresight compensator 240 is adjusted to align the moving lens stack 220 to the non-moving lens stack 210. Once proper alignment between the moving lens stack 220 and the non-moving lens stack 210 has been achieved, the boresight compensator 204 is locked. In other words, once the linear actuator 110 is precisely aligned, the adjustment mechanism (i.e., angular adjustment mechanism 150) is locked in place using, e.g., adhesives, bolts, screws, or clamps to ensure all components are securely fastened.

With reference to FIGS. 1 and 2, semiconductor yield issues can have significant and wide-ranging consequences for manufacturers, end-users, and the broader market. Consequences of semiconductor yield issues include economic impact, supply chain disruptions, quality and reliability concerns, research and development setbacks, market impact, environmental and resource impact, and end-user impact. To minimize the impact of yield issues, semiconductor manufacturers can employ several strategies such as process optimization, advanced monitoring, quality control, and research and development investment. The systems described above provide for further process optimization by incorporating an angular adjustment mechanism 150 with a linear actuator 110 to correct for off-axis motion of the linear actuator 110. The angular adjustment mechanism 150 is positioned between the reference surface and the linear actuator 110. This allows for the optimization of the linear off-axis motion of the linear actuator 110 with respect to the reference surface or reference plane. The reference plane is a stable, flat surface that serves as the baseline for alignment. The limitations (e.g., real off-axis true motion) become the residuals of this optimized axis travel (non-linearity/noise). By measuring the off-axis motion once, the system can determine the travel vector of the linear actuator 110 and compensate its travel vector to become perpendicular to the reference surface or reference plane. Once compensated, the system can re-measure the off-axis motion to determine the new aligned off-axis motion. In short, the system aligns the real or realized or actual axis of travel to the ideal axis of travel, rather than keeping the real-axis of travel to the theoretical axis of travel as an error in linear actuator production.

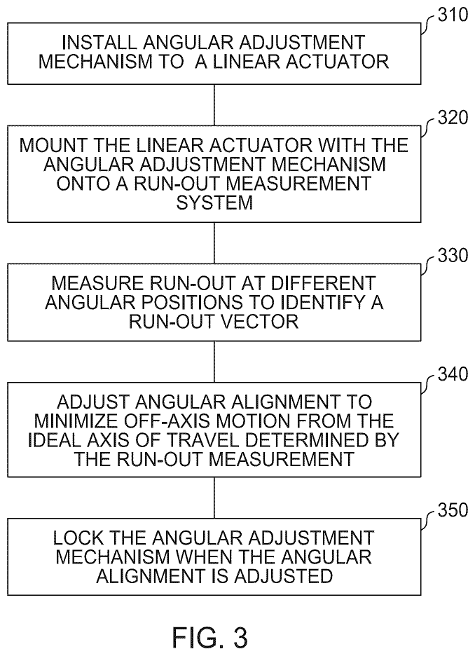

FIG. 3 is a flowchart of a method for implementing the linear actuator including compensation wedges for correcting off-axis motion of FIG. 1, according to one implementation.

Before any angular adjustment mechanism is placed on the linear actuator, the existing run-out is measured. Measuring the current run-out of the linear actuator involves assessing the deviation of the linear actuator's movement form its intended path.

At block 310, the angular adjustment mechanism is installed to a linear actuator. In one example, the angular adjustment mechanism includes a first compensation wedge and a second compensation wedge. The first compensation wedge is secured to the second compensation wedge such that together they form a rectangle or rectangular shape. In another embodiment, the angular adjustment mechanism is a single wedge that is cut with an angle to correct an angular error after measuring it.

At block 320, the linear actuator with the angular adjustment mechanism is mounted onto a run-out measurement system. The run-out measurement system measures run-out at different angles. For example, the run-out measurement system measures run-out at 0 degrees, at 45 degrees, and at 90 degrees to identify a vector of the run-out.

At block 330, run-out is measured at different angular positions to identify a vector of the run-out. For example, the run-out measurement system measures run-out at 0 degrees, at 45 degrees, and at 90 degrees to identify a vector of the run-out.

At block 340, the angular alignment is adjusted to minimize off-axis motion from the ideal axis of travel determined by the run-out measurement.

At block 350, the angular adjustment mechanism is locked when the angular alignment is adjusted. In other words, once the linear actuator is precisely aligned, the adjustment mechanism (i.e., angular adjustment mechanism) is locked in place using, e.g., adhesives, bolts, screws, or clamps to ensure all components are securely fastened.

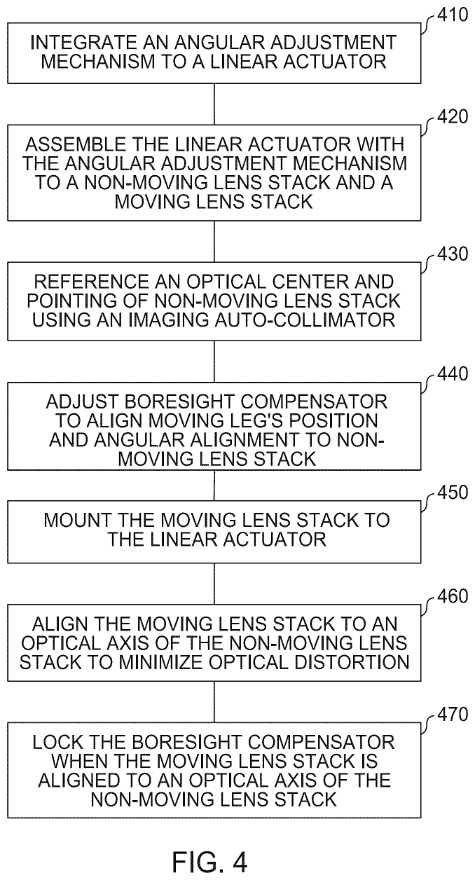

FIG. 4 is a flowchart of a method for implementing the linear actuator including compensation wedges for correcting off-axis motion of FIG. 2, according to one implementation. The following blocks may be performed in one or more different orders.

At block 410, an angular adjustment mechanism is integrated with a linear actuator. In one example, the angular adjustment mechanism includes a first compensation wedge and a second compensation wedge. The first compensation wedge is secured to the second compensation wedge such that together they form a rectangle or rectangular shape. In another embodiment, the angular adjustment mechanism is a single wedge that is cut with an angle to correct an angular error after measuring it.

At block 420, the linear actuator with the angular adjustment mechanism is assembled or secured to a non-moving lens stack and a moving lens stack. The non-moving lens stack remains fixed in position and serves as the stable mounting base for the linear actuator 110, the angular adjustment mechanism 150, and the moving lens stack 220.

At block 430, an optical center and pointing of non-moving lens stack is referenced using an imaging auto-collimator.

At block 440, a boresight compensator is adjusted to align the moving les' position and angular alignment to the non-moving lens stack.

At block 450, the moving lens stack is mounted to the linear actuator to provide for positional and angular alignment.

At block 460, the boresight compensator aligns the moving lens stack to an optical axis of the non-moving lens stack to minimize the optical distortion that can occur as the linear actuator moves.

At block 470, the boresight compensator is locked when the boresight compensator aligns the moving lens stack to the optical axis of the of the non-moving lens stack.

In conclusion, the example embodiments provide for an angular adjustment mechanism installed or incorporated or secured onto a linear actuator. The angular adjustment mechanism can correct the off-axis motion from the theoretical or ideal axis of travel. The angular adjustment mechanism includes compensation wedges. In one example, the angular adjustment mechanism includes a pair of wedges arranged to form a rectangular shape. The compensation wedges may be installed on a non-moving leg of the linear actuator. In another example, the compensation wedges may be incorporated or integrated or secured to a non-moving lens stack associated with the linear actuator. The angular adjustment mechanism is positioned between a reference surface (or reference plane) and the linear actuator. This positioning allows for the optimization of the linear off-axis motion of the linear actuator with respect to the reference surface. Moreover, the angular alignment or adjustment mechanism is integrated directly into the linear actuator, before the linear actuator is integrated into other systems. As such, the angular alignment or adjustment mechanism is intrinsic to the device (i.e., the linear actuator) and if adjusted does not propagate by angular or positional changes through components attached to the moving leg if this was to be completed on a device. Once aligned, any piezo and angular alignment pair can be placed into any device and require no adjustment. In other words, run-out is dealt with at the source so as to not affect downstream processes or components. In applications demanding extremely high precision, such as semiconductor manufacturing, even the smallest deviation can be critical.

The system provides for process optimization to increase the yield by incorporating or installing an angular adjustment mechanism with a linear actuator to correct for off-axis motion from the theoretical or ideal axis of travel. The angular adjustment mechanism is positioned between the reference surface and the linear actuator. The limitations (e.g., real off-axis true motion) become the residuals of this optimized axis travel (non-linearity/noise). By measuring the off-axis motion once, the system can determine the travel vector of the linear actuator and align its travel vector to become perpendicular to the reference surface. Once compensated, the system can re-measure the off-axis motion to determine the new aligned off-axis motion. In short, the system aligns the real or actual or realized axis of travel to the ideal axis of travel, rather than keeping the real axis of travel to the theoretical axis of travel as an error in linear actuator production. The real versus ideal errors that are being corrected for are very small as they are intrinsic to each individual linear actuator.

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

As used herein, “a CPU” “, controller”, “a processor”, “at least one processor”, or “one or more processors”, generally refers to a single processor configured to perform one or multiple operations or multiple processors configured to collectively perform one or more operations. In the case of multiple processors, the one or more operations could be divided amongst different processors, though one processor may perform multiple operations, and multiple processors could collectively perform a single operation. Similarly, “a memory” “, at least one memory”, or “one or more memories”, generally refers to a single memory configured to store data and/or instructions, multiple memories configured to collectively store data and/or instructions.

As used herein, “gas” and “fluid” may be used interchangeable with either term generally referring to elements, compounds, materials, etc., having the properties of a gas, a fluid, or both a gas and a fluid.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some” refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

“Coupled” and “coupling” means that the subsequently described material is connected to previously described material. The connection may be a direct, or indirect connection, and may, or may not, include intermediary components such as plumbing, wiring, fasteners, mechanical power transmission, electrical communication, wired and/or wireless transmission, etc., which may be suitable to affect operation of the components.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining”may include resolving, selecting, choosing, and establishing.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S. C. § 112(f), for any limitations of any of the claims, except for those in which the claim expressly uses the words ‘means for’ together with an associated function.

While the foregoing is directed to embodiments of the present disclosure, other and further embodiments of the disclosure may be devised without departing from the basic scope thereof, and the scope thereof is determined by the claims that follow.

What is claimed is:

1. A linear actuator, comprising:
a body;
a non-moving section extending from the body; and
an angular adjustment mechanism secured on the non-moving section, wherein the angular adjustment mechanism corrects off-axis motion relative to an ideal axis of travel of the linear actuator.

2. The linear actuator of claim 1, wherein the angular adjustment mechanism includes a first compensation wedge and a second compensation wedge.

3. The linear actuator of claim 2, wherein the first compensation wedge and the second compensation wedge are arranged to form a rectangular shape.

4. The linear actuator of claim 1, wherein the angular adjustment mechanism includes a single wedge.

5. The linear actuator of claim 4, wherein the single wedge is cut with an angle to correct an angular error after measurement.

6. The linear actuator of claim 1, wherein the linear actuator is secured onto a run-out measurement device.

7. The linear actuator of claim 6, wherein the run-out measurement device measures run-out at different angles to identify vectors representative of a maximum run-out vector.

8. The linear actuator of claim 7, wherein a run-out is adjusted to minimize the off-axis motion relative to the ideal axis of travel of the linear actuator by aligning a realized axis of travel to the ideal axis of travel.

9. The linear actuator of claim 8, wherein the angular adjustment mechanism is locked when the ideal axis of travel and the real axis of travel are aligned to minimize the off-axis motion relative to the ideal axis of travel.

10. The linear actuator of claim 1, wherein the linear actuator includes a reference prism and a measurement prism, wherein the angular adjustment mechanism has an axis of rotation that is in-plane with surfaces of the reference prism and in-plane with a surface of the measurement prism.

11. A linear actuator, comprising:
a body;
a moving section extending from the body; and
an angular adjustment mechanism secured between a non-moving section and a non-moving lens stack, wherein the angular adjustment mechanism corrects off-axis motion relative to an ideal axis of travel of the linear actuator.

12. The linear actuator of claim 11, wherein the angular adjustment mechanism includes a first compensation wedge and a second compensation wedge.

13. The linear actuator of claim 12, wherein the first compensation wedge and the second compensation wedge are arranged to form a rectangular shape.

14. The linear actuator of claim 11, wherein a boresight compensator is secured to the moving section.

15. The linear actuator of claim 14, wherein a moving lens stack is coupled to the linear actuator to provide for positional and angular alignment.

16. The linear actuator of claim 15, wherein the boresight compensator aligns the moving lens stack to an optical axis of the non-moving lens stack to minimize optical distortion.

17. The linear actuator of claim 16, wherein the angular adjustment mechanism is locked when the boresight compensator aligns the moving lens stack to the optical axis of the of the non-moving lens stack.

18. A method, comprising:
securing an angular adjustment mechanism to a linear actuator;
mounting the linear actuator to a run-out measurement device;
measuring, by the run-out measurement device, run-out at different angles to identify a run-out vector; and
adjusting an angular alignment to minimize off-axis motion from an ideal axis of travel determined by the run-out measurement device.

19. The method of claim 18, wherein the angular adjustment mechanism includes a first compensation wedge and a second compensation wedge.

20. The method of claim 19, wherein the first compensation wedge and the second compensation wedge are arranged to form a rectangular.
